(19) United States
(12) Patent Application Publication
(10) Pub. No.: US 2017/0309716 A1
(43) Pub. Date: Oct. 26, 2017

(54) SEMINCONDUCTOR DEVICE AND MANUFACTURING METHOD OF THE SAME

(71) Applicant: TOYOTA JIDOSHA KABUSHIKI KAISHA, Toyota-shi, Aichi-ken (JP)

(72) Inventors: Jun SAITO, Toyota-shi (JP); Atsushi ONOGI, Toyota-shi (JP); Sachiko AOI, Nagakute-shi (JP); Shinichiro MIYAHARA, Nagoya-shi (JP)

(73) Assignee: TOYOTA JIDOSHA KABUSHIKI KAISHA, Toyota-shi, Aichi-ken (JP)

(21) Appl. No.: 15/517,231

(22) PCT Filed: Jul. 22, 2015
(86) PCT No.: PCT/JP2015/070890

§ 371 Date: Apr. 6, 2017

(30) Foreign Application Priority Data
Dec. 10, 2014 (JP) 2014-249818

(51) Int. Cl. H01L 29/423; H01L 29/78; H01L 29/66; H01L 29/06

(52) U.S. Cl. CPC H01L 29/4236; H01L 29/0619; H01L 29/0692; H01L 29/7827; H01L 29/66666

(57) ABSTRACT

A semiconductor device includes a semiconductor substrate in which a semiconductor element is provided and a covering insulation film provided on the semiconductor substrate. The semiconductor substrate includes a first portion and a second portion which has a thickness thinner than a thickness of the first portion. A step portion is provided at a part where the first portion and the second portion adjoin to each other. A corner member is provided at a corner between a side surface of the step portion and an upper surface of the second portion. An upper surface of the corner member slopes downward from the side surface of the step portion toward the second portion. The covering insulation film extends over from the first portion to the second portion, and covers the corner member.

### TECHNICAL FIELD

A technique disclosed in the present specification relates to a semiconductor device and a manufacturing method of the same.

### BACKGROUND

Patent Literature 1 (Japanese Patent Application Publication No. 2012-009502) discloses a semiconductor device. The semiconductor device of the Patent Literature 1 includes a semiconductor substrate and a covering insulation film provided on the semiconductor substrate. The semiconductor substrate includes a first portion and a second portion which has a thickness thinner than a thickness of the first portion, and the first portion and the second portion adjoin to each other. The covering insulation film extends over from the first portion to the second portion.

### TECHNICAL PROBLEM

In the semiconductor device of Patent Literature 1, a void sometimes may occur in the covering insulation film. For example, when a current flows in the semiconductor device, the semiconductor substrate generates heat, a temperature of the covering insulation film on the semiconductor substrate becomes high, and a void may occur due to the high temperature of the covering insulation film. Further, not only during an operation of the semiconductor device but also when the covering insulation film is formed on the semiconductor substrate, stress may be generated within the covering insulation film and a crack may occur thereby. Especially in a part where the first portion and the second portion having different thicknesses adjoin to each other, compared to its surrounding part, the void and crack are likely to occur in the covering insulation film on the semiconductor substrate. Due to this, there is a problem that breakdown voltage of the covering insulation film decreases due to the void and crack. Therefore, the present specification offers a technique in which a decrease in breakdown voltage of a covering insulation film can be suppressed.

### SOLUTION TO TECHNICAL PROBLEM

A semiconductor device disclosed in the present specification may comprise a semiconductor substrate in Which a semiconductor element is provided and a covering insulation film provided on the semiconductor substrate. The semiconductor substrate may comprise a first portion and a second portion which has a thickness thinner than a thickness of the first portion. A step portion may be provided at a part where the first portion and the second portion adjoin each other. A corner member may be provided at a corner between a side surface of the step portion and an upper surface of the second portion. An upper surface of the corner member may slope downward from the side surface of the step portion toward the second portion. The covering insulation film may extend over from the first portion to the second portion, and covers the corner member.

In this semiconductor device, due to the presence of the corner member, a curve of the covering insulation film covering the corner member is gentle. According to this configuration, even when a temperature of the covering insulation film becomes high due to the semiconductor substrate generating heat, a void can be suppressed from occurring in the covering insulation film at the corner. Further, since the curve of the covering insulation film is gentle, stress generated within the covering insulation film at the corner can be reduced, as a result of which a crack can be suppressed from occurring in the covering insulation film. As above, the void and crack can be suppressed from occurring in the covering insulation film, and breakdown voltage of the covering insulation film can be suppressed from decreasing.

A method of manufacturing a semiconductor device that comprises: a semiconductor substrate comprising a first portion, a second portion which has a thickness thinner than a thickness of the first portion, and a step portion provided at a part where the first portion and the second portion adjoin each other, the method may comprise forming a corner member at a corner between a side surface of the step portion and an upper surface of the second portion, wherein an upper surface of the corner member slopes downward from the side surface of the step portion toward the second portion. The method may further comprise forming the covering insulation film extending over from the first portion to the second portion so that the corner member is covered by the covering insulation film.

### BRIEF DESCRIPTION OF DRAWINGS

FIG. 1 is a top view of a semiconductor device;

FIG. 2 is a cross sectional view along II-II of FIG. 1;

FIG. 3 is an enlarged view of a main section III of FIG. 2;

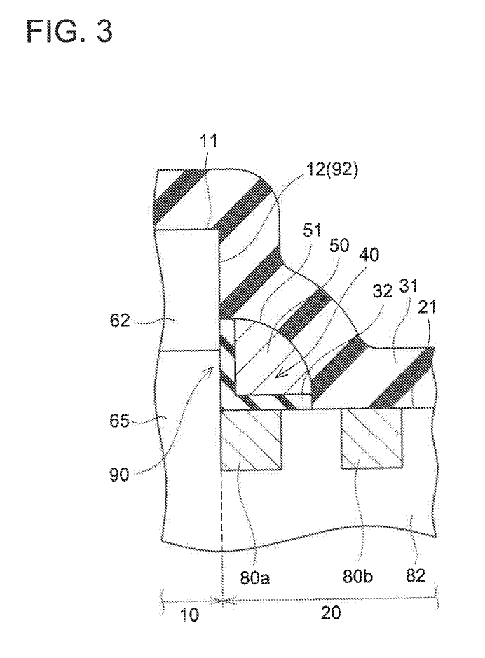

FIG. 4 is a view (1) for explaining a manufacturing method of the semiconductor device;

FIG. 5 is a view (2) for explaining the manufacturing method of the semiconductor device;

FIG. 6 is a view (3) for explaining the manufacturing method of the semiconductor device;

FIG. 7 is a view (4) for explaining the manufacturing method of the semiconductor device;

FIG. 8 is a view (5) for explaining the manufacturing method of the semiconductor device;

FIG. 9 is a view (6) for explaining the manufacturing method of the semiconductor device;

FIG. 10 is a view (7) for explaining the manufacturing method of the semiconductor device;

FIG. 11 is a view (8) for explaining the manufacturing method of the semiconductor devices;

FIG. 12 is an enlarged view of a main section of a semiconductor device according to another embodiment;

FIG. 13 is a view for explaining a manufacturing method of the semiconductor device according to the other embodiment;

FIG. 14 is an enlarged view of a main section of a semiconductor device according to yet another embodiment;

FIG. 15 is an enlarged view of a main section of a semiconductor device according to yet another embodiment; and

FIG. 16 is an enlarged view of a main section of a semiconductor device according to yet another embodiment.

### DESCRIPTION OF EMBODIMENTS

### First Embodiment

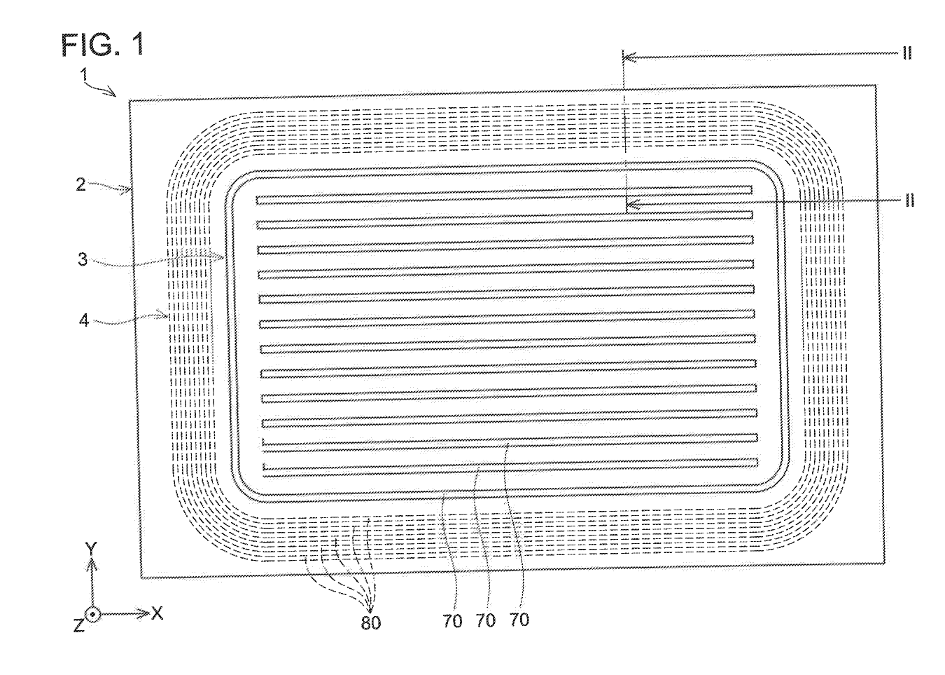

With reference to the attached drawings, embodiments will be described below. As shown in FIG. 1, a semiconductor device 1 according to a first embodiment comprises a rectangular semiconductor substrate 2. The semiconductor substrate 2 is made of silicon carbide (SiC). In another embodiment, the semiconductor substrate 2 may be made of silicon (Si), gallium nitride (GaN), or the like. A semiconductor element is provided within the semiconductor substrate 2.

The semiconductor substrate 2 is provided with an element region 3 and a peripheral region 4. The element region 3 is provided on an inner side relative to the peripheral region 4. The element region 3 is provided with a semiconductor element. In the present embodiment, a vertical MOSFET (Metal Oxide Semiconductor Field Effect Transistor) is provided in the element region 3. The peripheral region 4 is provided on an outer side relative to the element region 3. The peripheral region 4 is provided with a high breakdown voltage structure. FIG. 1 shows only trenches 70 in the element region 3 and only field limiting rings 80 in the peripheral region 4 for easier view of the figure.

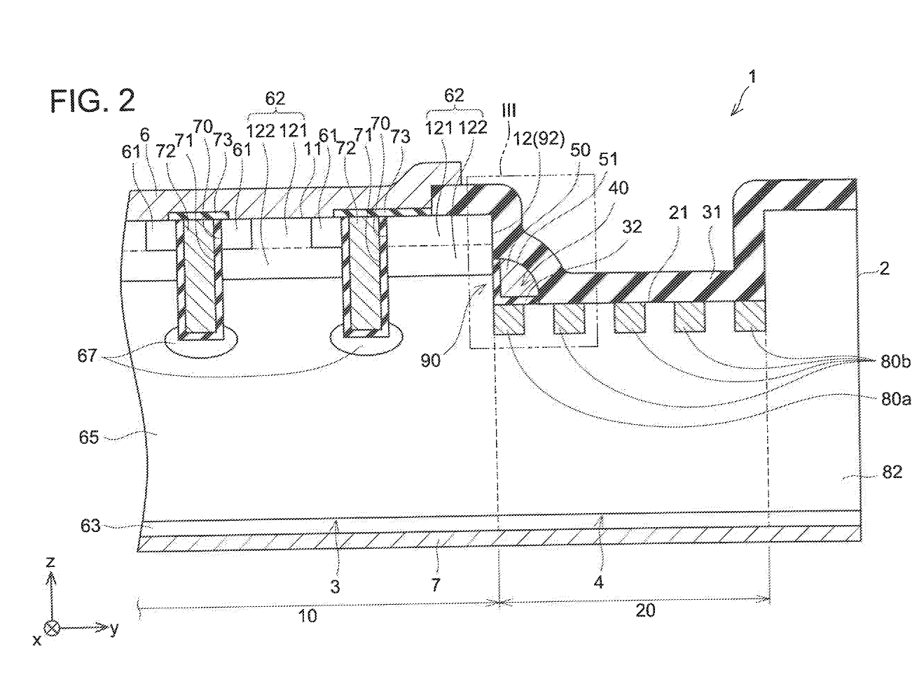

As shown in FIG. 2, the semiconductor device 1 comprises the semiconductor substrate 2, a front surface electrode 6, and a rear surface electrode 7. Further, the semiconductor device 1 comprises a separating insulation film 32, a corner member 50, and a covering insulation film 31.

The semiconductor substrate 2 comprises a first portion 10 and a second portion 20. The element region 3 is provided in the first portion 10. The peripheral region 4 is provided in the second portion 20. A thickness of the first portion 10 is thicker than a thickness of the second portion 20 (the thickness of the second portion 20 is thinner than the thickness of the first portion 10). The first portion 10 and the second portion 20 are provided so as to adjoin to each other. A step portion 90 is provided at a part where the first portion 10 and the second portion 20 adjoin to each other.

The step portion 90 is formed by a thickness difference between the first portion 10 and the second portion 20. A position of an upper surface 11 of the first portion 10 is above a position of an upper surface 21 of the second portion 20, and the step portion 90 is formed by the difference between the positions of the upper surfaces. The step portion 90 comprises a part of the upper surface 11 of the first portion 10, a side surface 12 of the first portion 10, and a part of the upper surface 21 of the second portion 20. Hereinbelow, the side surface 12 of the first portion 10 may be referred to as a side surface 92 of the step portion 90. A corner 40 is provided between the side surface 92 of the step portion 90 and the upper surface 21 of the second portion 20.

The plurality of trenches 70 is provided in the first portion 10 of the semiconductor substrate 2. Further, source regions 61, a base region 62, a drift region 65, a drain region 63, and floating regions 67 are provided in the first portion 10.

The trenches 70 are recesses provided in the upper surface 11 of the first portion 10. The trenches 70 extend in a depth direction of the semiconductor substrate 2 (z direction). Each of the trenches 70 extend to a depth reaching the drift region 65 from the upper surface 11 of the first portion 10 passing through the corresponding source regions 61 and the base region 62.

A gate insulation film 71 is provided on an inner surface of each trench 70. A gate electrode 72 is arranged in each trench 70. Each of the gate insulation films 71 is formed by an oxide film being deposited on the inner surface of corresponding one of the trenches 70. For example, a silicon dioxide film (SiO2) can be used as the gate insulation film 71. Each of the gate electrodes 72 fills an inner side of corresponding one of the gate insulation films 71. The gate electrodes 72 are insulated from the semiconductor substrate 2 by the gate insulation films 71. The gate electrodes 72 are made of aluminum or polysilicon, for example. An interlayer insulation film 73 is arranged on each of the gate electrodes 72.

The source regions 61 are of an n-type. The source regions 61 have a high impurity concentration. The source regions 61 are provided in a front layer part of the semiconductor substrate 2. The source regions 61 are provided in a range exposed on the upper surface 11 of the first portion 10 in islands. Each of the source regions 61 is in contact with corresponding one of the gate insulation films 71. The source regions 61 are in contact with the front surface electrode 6. The source regions 61 are in ohmic contact with the front surface electrode 6 and electrically connected to the front surface electrode 6.

The base region 62 is of a p-type. The base region 62 provided in a surrounding of the source regions 61. The base region 62 is provided next to and below the source regions 61. The base region 62 is in contact with the gate insulation films 71. Further, the base region 62 is provided in a range exposed on the side surface 92 of the step portion 90. The base region 62 comprises a base contact region 121 and a low-concentration base region 122. The base contact region 121 has a high impurity concentration. An impurity concentration of the low-concentration base region 122 is lower than that of the base contact region 121.

The base contact region 121 is provided in the front layer part of the semiconductor substrate 2. The base contact region 121 is provided in a region exposed on the upper surface 11 of the first portion 10 in islands. The base contact region 121 is in contact with the front surface electrode 6. The base contact region 121 is in ohmic contact with the front surface electrode 6 and electrically connected to the front surface electrode 6.

The low-concentration base region 122 is provided below the source regions 61 and the base contact region 121. The source regions 61 are separated from the drift region 65 by the low-concentration base region 122.

The drift region 65 is of the n-type. The drift region 65 has a low impurity concentration. The drift region 65 is provided below the base region 62. The drift region 65 is in contact with the gate insulation films 71,

The drain region 63 is of the n-type. The drain region 63 has a high impurity concentration. The drain region 63 is provided below the drift region 65. The drain region 63 is provided in a region exposed on a rear surface of the semiconductor substrate 2. The drain region 63 is in contact with the rear surface electrode 7. The drain region 63 is in ohmic contact with the rear surface electrode 7 and electrically connected to the rear surface electrode

The floating regions 67 are of the p-type. Each of the floating regions 67 is provided in a surrounding of a bottom portion of corresponding one of the trenches 70. Each of the floating regions 67 is in contact with the bottom portion of the corresponding trench 70. The drift region 65 is provided in surroundings of the floating regions 67. The floating regions 67 are surrounded by the drift region 65. The floating regions 67 are separated from the base region 62 by the drift region 65. The floating regions 67 are separated from each other by the drift region 65.

The plurality of field limiting rings 80 and a peripheral drift region 82 are provided in the second portion 20 of the semiconductor substrate 2.

The plural field limiting rings 80 (hereinbelow, “field limiting ring” will be referred to as “FLR”) are provided at intervals. The FLRs 80 are of the p-type. The FLRs 80 have a high impurity concentration. The FLRs 80 are provided in a range exposed on the upper surface 21 of the second portion 20.

The FLR 80 which is the nearest to the first portion 10 among the plural FLRs 80 is indicated by a reference sign “80a”, and the other FLRs 80 are indicated by a reference sign “80b”. The FLR 80a which is the nearest to the first portion 10 is provided under the corner 40. The drift region 65 is provided between the FLR 80a and the base region 62. The FLR 80a is separated from the base region 62 by the drift region 65.

The peripheral drift region 82 is provided in surroundings of the FLRs 80. The peripheral drift region 82 is provided between the FLRs 80 and below the FLRs 80, and separates the FLRs 80 from each other.

The front surface electrode 6 is provided on the upper surface 11 of the first portion 10 of the semiconductor substrate 2. The front surface electrode 6 is insulated from the gate electrodes 72 by the interlayer insulation films 73. The rear surface electrode 7 is provided on rear surfaces of the first portion 10 and the second portion 20 of the semiconductor substrate 2. The front surface electrode 6 and the rear surface electrode 7 are made of a metal such as aluminum (Al), copper (Cu), or the like.

The separating insulation film 32 covers, at the corner 40, the side surface 92 of the step portion 90 and the upper surface 21 of the second portion 20. The separating insulation film 32 is provided between the corner member 50 and the semiconductor substrate 2, and separates the corner member 50 from the semiconductor substrate 2. A silicon dioxide film (SiO2) can be used as the separating insulation film 32. The separating insulation film 32 is made of a same material as the gate insulation films 71. The separating insulation film 32 can be formed by depositing an oxide film.

The corner member 50 is provided on the separating insulation film 32. The corner member 50 is arranged at the corner 40. The corner member 50 has electrical conductivity.

For example, polysilicon can be used as a material of the corner member 50. The corner member 50 is made of the same material as the gate electrodes 72. In another example, the corner member 50 may be made of a metal.

The corner member 50 comprises an upper surface 51. In the present embodiment, the upper surface 51 of the corner member 50 is formed as a convexly curved surface. The upper surface 51 of the corner member 50 slopes downward from a step portion 90 side toward the second portion 20. Therefore, the upper surface 51 of the corner member 50 continuously slopes downward from the side surface 92 of the step portion 90 toward the second portion 20. A height of the corner member 50 is lower than the height difference (the step) between the upper surface 11 of the first portion 10 and the upper surface 21 of the second portion 20. The upper surface 51 of the corner member 50 is positioned lower than the upper surface 11 of the first portion 10. The curved upper surface 51 is covered with the covering insulation film 31.

The corner member 50 faces the side surface 92 of the step portion 90 via the separating insulation film 32. That is, the corner member 50 faces the base region 62 via the separating insulation film 32. Further, the corner member 50 faces the upper surface 21 of the second portion 20 via the separating insulation film 32. The corner member 50 faces the FIR 80a which is the nearest to the first portion 10 via the separating insulation film 32.

The covering insulation film 31 covers the upper surface 21 of the second portion 20. Further, a part of the covering insulation film 31 covers the upper surface 11 of the first portion 10 in a vicinity of the second portion 20. That is, the covering insulation film 31 extends over from the first portion 10 of the semiconductor substrate 2 to the second portion 20 of the semiconductor substrate 2. The covering insulation film 31 covers the side surface 92 of the step portion 90. Further, the covering insulation film 31 covers the curved upper surface 51 of the corner member 50. An entirety of the corner member 50 is covered with the covering insulation film 31 and the separating insulation film 32. A thickness of the covering insulation film 31 is thicker than a thickness of the separating insulation film 32. A silicon dioxide film (SiO2) can be used as the covering insulation film 31. The covering insulation film 31 can be formed by depositing an oxide film.

When the semiconductor device 1 comprising the above-mentioned configuration is used, a voltage which makes the rear surface electrode 7 positive is applied between the front surface electrode 6 and the rear surface electrode 7. Further, an on-voltage (voltage which is equal to or greater than a voltage required to form channels) is applied to the gate electrodes 72. When the on-voltage is applied to the gate electrodes 72, channels are formed in the low-concentration base region 122 in a range being in contact with the gate insulation films 71. Due to this, the MOSFET is turned on. At this occasion, electrons flow from the front surface electrode 6 to the rear surface electrode 7 through the source regions 61, the channels formed in the low-concentration base region 122, the drift region 65, and the drain region 63. Further, holes flow from the rear surface electrode 7 to the front surface electrode 6 through the drain region 63, the drift region 65, the low-concentration base region 122, and the base contact region 121. Thereby, a current flows from the rear surface electrode 7 to the front surface electrode 6.

When the current flows in the semiconductor device 1, the semiconductor substrate 2 generates heat, and temperatures of the separating insulation film 32 and the covering insulation film 31 provided on the semiconductor substrate 2 become high. According to the above-mentioned configuration of the semiconductor device 1, the corner 40 is provided between the side surface 92 of the step portion 90 and the upper surface 21 of the second portion 20 of the semiconductor substrate 2, and the covering insulation film 31 covers the corner member 50 arranged at the corner 40. Due to this, compared to a case where the covering insulation film 31 directly contacts the corner 40, a curve of the covering insulation film 31 is gentle. Especially, in the semiconductor device 1, the corner member 50 comprises the upper surface 51 which is curved convexly, and thus the curve of the covering insulation film 31 covering the corner member 50 is gentler. Due to the curve of the covering insulation film 31 being gentle as above, even when the temperature of the covering insulation film 31 in a vicinity of the corner 40 becomes high, bubbles are less likely to grow within the covering insulation film. Therefore, the void can be suppressed from occurring in the covering insulation film 31 at the corner 40. Further, since the curve of the covering insulation film 31 at the corner 40 is gentle, stress generated within the covering insulation film 31 when the semiconductor substrate 2 generates heat can be moderated. Due to this, the crack can be suppressed from occurring in the covering insulation film 31. Therefore, a decrease in breakdown voltage of the covering insulation film 31 can be suppressed. It should be noted, although the separating insulation film 32 is bent sharply, the thickness thereof is thin, and thus no overstress is generated.

Further, in the above-mentioned semiconductor device 1, the conductive corner member 50 faces each of the base region 62 and the FIR. 80 via the separating insulation film 32. When the MOSFET is turned off, a potential of the corner member 50 becomes a potential which is intermediate between a potential of the base region 62 and a potential of the FLR 80, and an electric field at the corner 40 is moderated. As a result, breakdown voltage of the separating insulation film 32 at the corner 40 can be enhanced. Further, in the above-mentioned semiconductor device 1, the corner member 50 and the gate electrodes 72 are made of the same material. Due to this, as described later, the corner member 50 and the gate electrodes 72 can be formed at a same time.

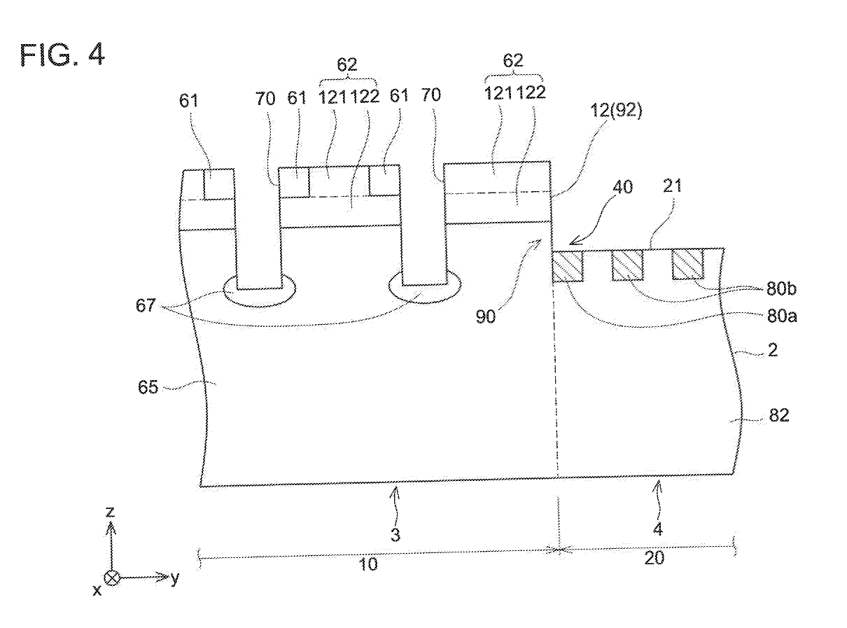

Next, a manufacturing method of the semiconductor device 1 comprising the above mentioned configuration will be described. The semiconductor device 1 is manufactured from the n-type semiconductor substrate 2 containing n-type impurities which are substantially the same as those in the drift region 65 and the peripheral drift region 82. Firstly, the semiconductor substrate 2 is processed as shown in FIG. 4. That is, the semiconductor substrate 2 is processed such that it includes the thick first portion 10 and the thin second portion 20. Further, the trenches 70, the source regions 61, the base region 62, the floating regions 67, and the FLRs 80 are firmed in the semiconductor substrate 2. Since publicly known techniques can be used for these processes, detailed explanations thereof will be omitted.

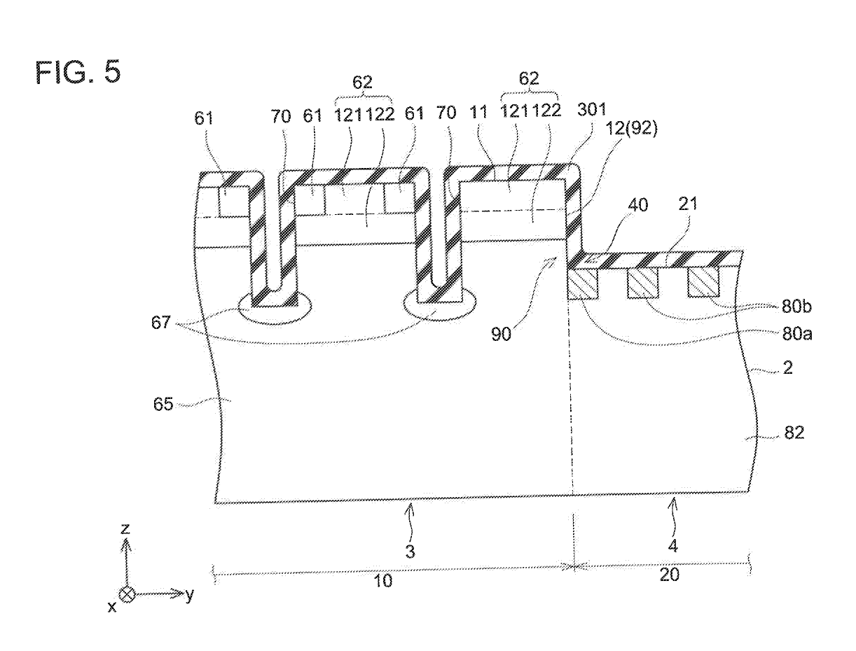

Next, as shown in FIG. 5, a step of depositing a material 301 of the separating insulation film on an upper surface of the semiconductor substrate 2 is performed. As described above, the semiconductor substrate 2 comprises the first portion 10 and the second portion 20 which has the thickness thinner than that of the first portion 10, and the step portion 90 is provided at the part where the first portion 10 and the second portion 20 adjoin to each other. The separating insulation film material 301 is deposited on the upper surface 11 of the first portion 10 and the upper surface 21 of the second portion 20. Further, the separating insulation film material 301 is deposited on the side surface 92 of the step portion 90 as well. Further, the separating insulation film material 301 is also deposited at the corner 40 between the side surface 92 of the step portion 90 and the upper surface 21 of the second portion 20. Further, the separating insulation film material 301 is deposited on the inner surfaces of the trenches 70 as well. For example, SiO2 can be used as the separating insulation film material 301.

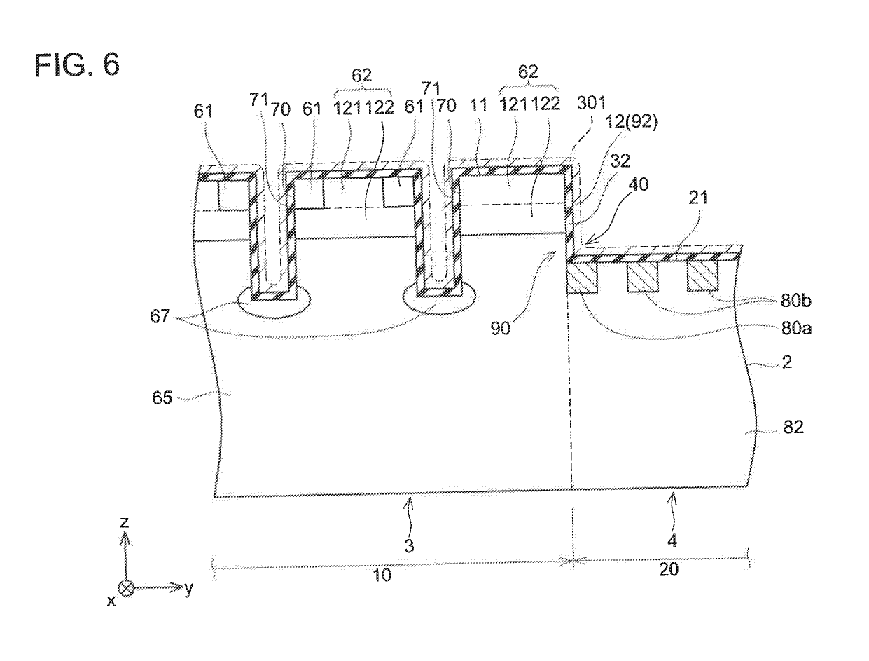

Next, as shown in FIG. 6, a step of etching the separating insulation film material 301 deposited on the upper surface of the semiconductor substrate 2 is performed. When the separating insulation film material 301 is etched, the etching is performed such that a part of the separating insulation film material 301 is left on the upper surface of the semiconductor substrate 2. Further, the etching is performed such that a part of the separating insulation film material 301 is left on the inner surfaces of the trenches 70. The gate insulation films 71 are formed by the separating insulation film material 301 that is left on the inner surfaces of the trenches 70.

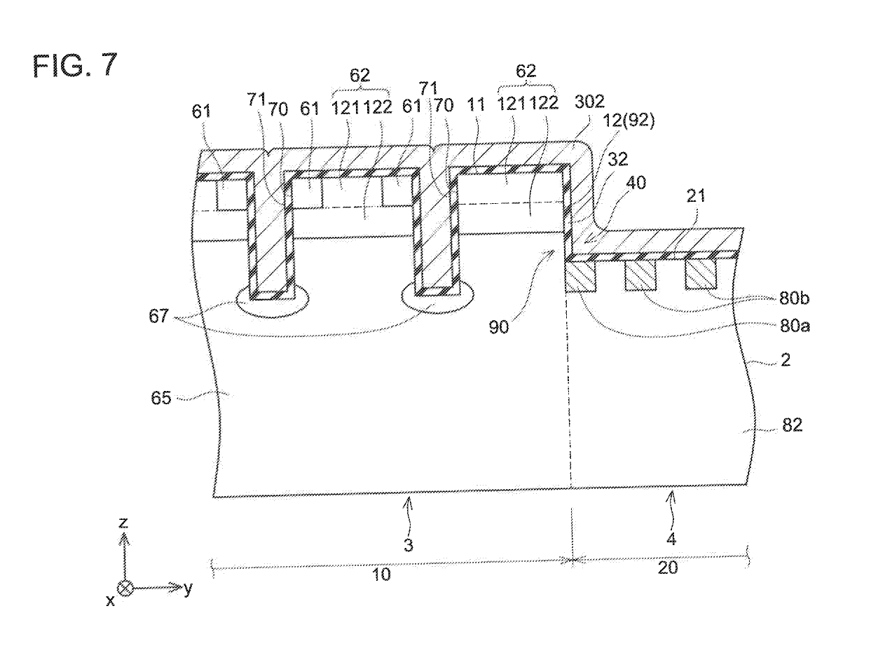

Next, as shown in FIG. 7, a step of depositing a material 302 of the corner member on an upper surface of the separating insulation film material 301 is performed. The corner member material 302 is deposited on the separating insulation film material 301 at the first portion 10 and the second portion 20 of the semiconductor substrate 2. The corner member material 302 is also deposited at the corner 40 between the side surface 92 of the step portion 90 and the upper surface 21 of the second portion 20. Further, the corner member material 302 is deposited in the trenches 70 as well. The corner member material 302 is deposited on surfaces of the gate insulation films 71. As above, the corner member material 302 is deposited on the semiconductor substrate 2. Polysilicon can be used as the corner member material 302.

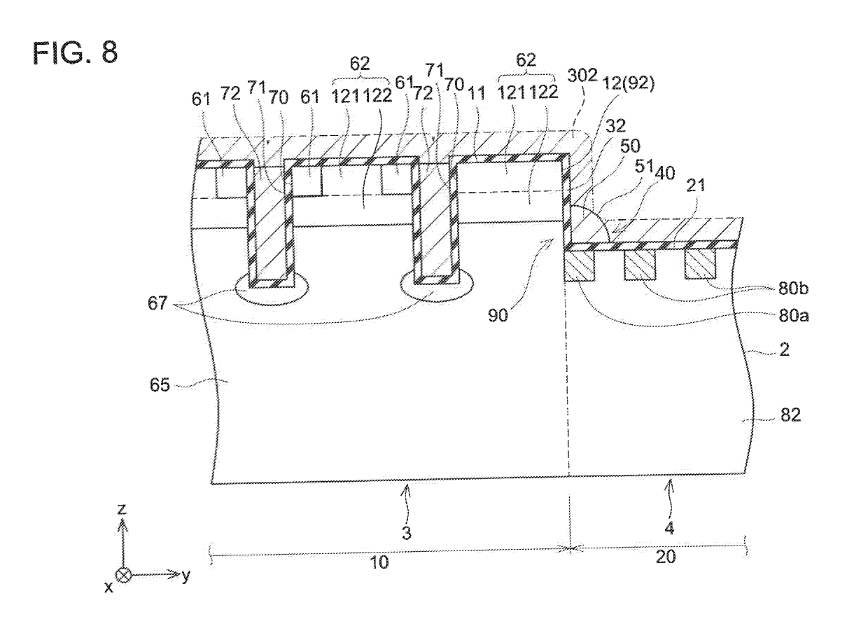

Next, as shown in FIG. 8, a step of etching the corner member material 302 is performed. When the corner member material 302 is etched, the etching is performed such that a part of the corner member material 302 is left at the corner 40. Further, the etching is performed such that a part of the corner member material 302 is left in the trenches 70. Due to the corner member material 302 being left at the corner 40, the corner member 50 is formed at the corner 40. Further, due to the corner member material 302 being left in the trenches 70, the gate electrodes 72 are formed in the trenches 70. As above, the corner member 50 and the gate electrodes 72 are formed. The corner member 50 is formed such that the upper surface 51 slopes downward from the side surface 92 of the step portion 90 toward the second portion 20. Further, the separating insulation film material 301 between the corner member 50 and the semiconductor substrate 2 becomes the separating insulation film 32.

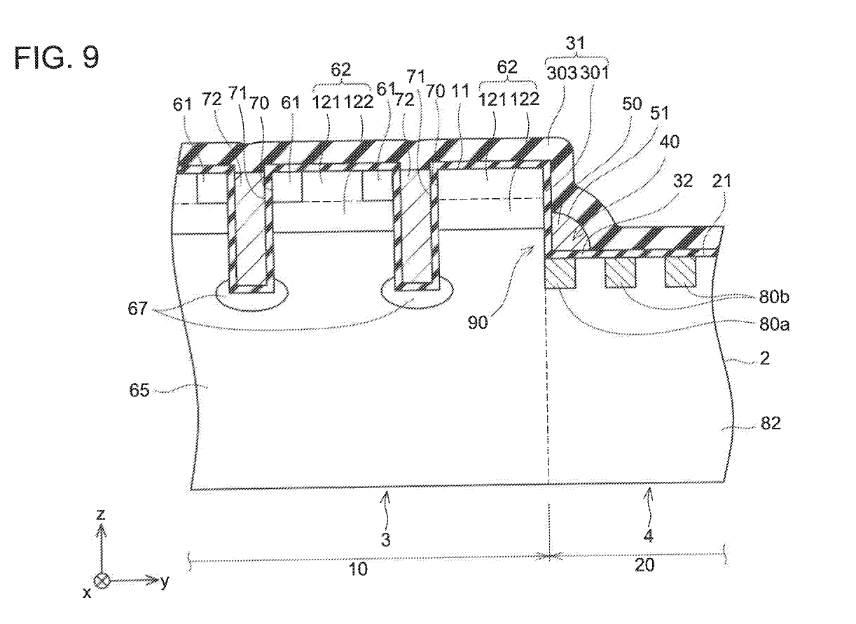

Next, as shown in FIG. 9, a step of depositing a material 303 of the covering insulation film on the separating insulation film material 301 and the corner member 50 is performed. The covering insulation film material 303 covers the corner member 50. SiO2 can be used as the covering insulation film material 303, for example. At places where the covering insulation film material 303 and the separating insulation film material 301 contact with each other, these two insulation film materials integrate. By the integrated insulation film materials as such, the covering insulation film 31 is formed. The covering insulation film 31 extends over from the first portion 10 to the second portion 20, and covers the corner member 50.

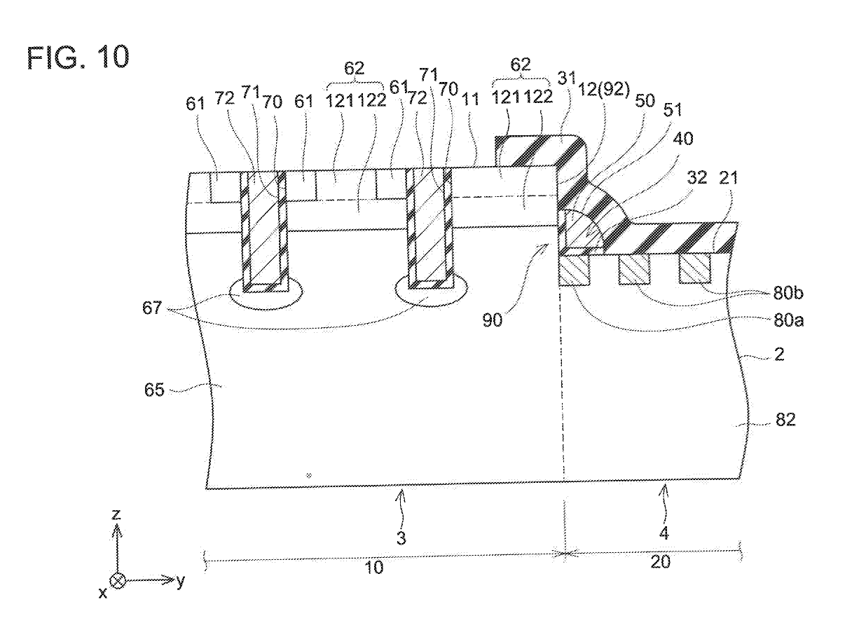

Next, as shown in FIG. 10, a step of etching an unnecessary part of the covering insulation film 31 is performed. By the etching, the covering insulation film 31 formed on the gate electrodes 72 is removed and upper surfaces of the gate electrodes 72 are exposed. Further, the covering insulation film 31 and the separating insulation film 32 formed on a part of the first portion 10 is removed and the part of the first portion 10 is exposed.

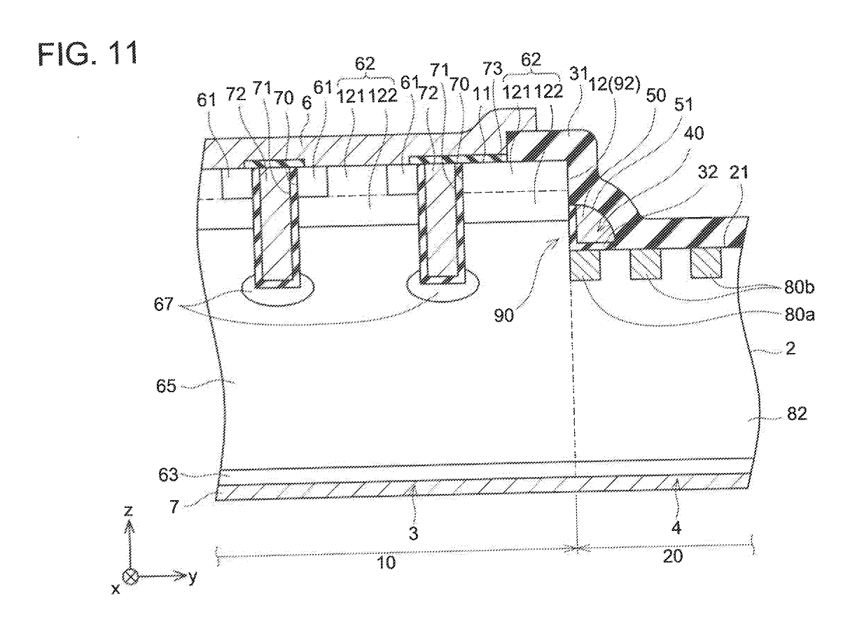

Next, as shown in FIG. 11, the interlayer insulation film 73 is formed on each of the exposed gate electrodes 72. Further, the front surface electrode 6 is formed on the exposed upper surface of the first portion 10. Next, the drain region 63 is formed on a rear surface side of the semiconductor substrate 2. Further, the rear surface electrode 7 is formed on the rear surface of the semiconductor substrate 2. The semiconductor device 1 shown in FIG. 1 is manufactured as described above.

According to the above-mentioned manufacturing method, since the corner member 50 is formed at the corner 40, the covering insulation film 31 covers the corner member 50 when formed, and thus the curve of the covering insulation film 31 at the corner 40 becomes gentle. Due to this, the stress generated within the covering insulation film 31 can be reduced, and the crack can be suppressed from occurring in the covering insulation film 31. Further, the gate insulation films 71 can be formed by using the step of forming the separating insulation film 32. Further, the gate electrodes 72 can be formed by using the step of forming the corner member 50.

(Correspondence Relationships)

In the above embodiment, the base region 62 is an example of “first region”, the field limiting ring 80a that is the nearest to the first portion 10 is an example of “second region”, and the drift region 65 is an example of “third region”.

One embodiment has been described above, however, specific aspects are not limited to the above-mentioned embodiment. Hereinbelow, configurations same as the configurations described above will be given the same reference signs, and explanations thereof will be omitted.

### Second Embodiment

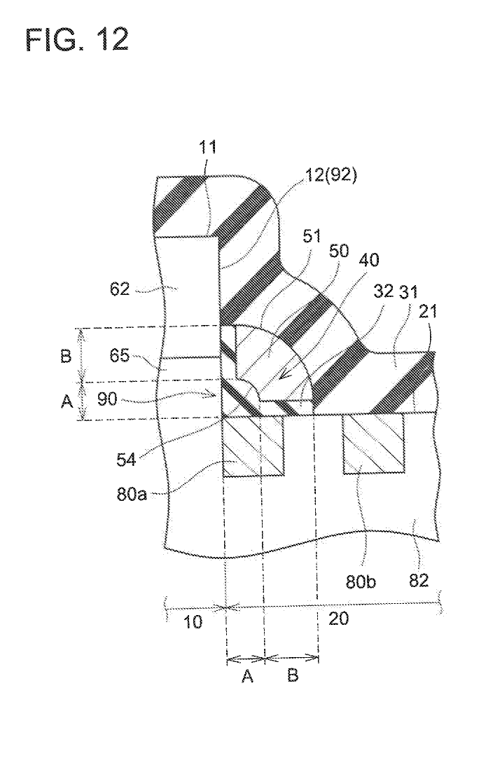

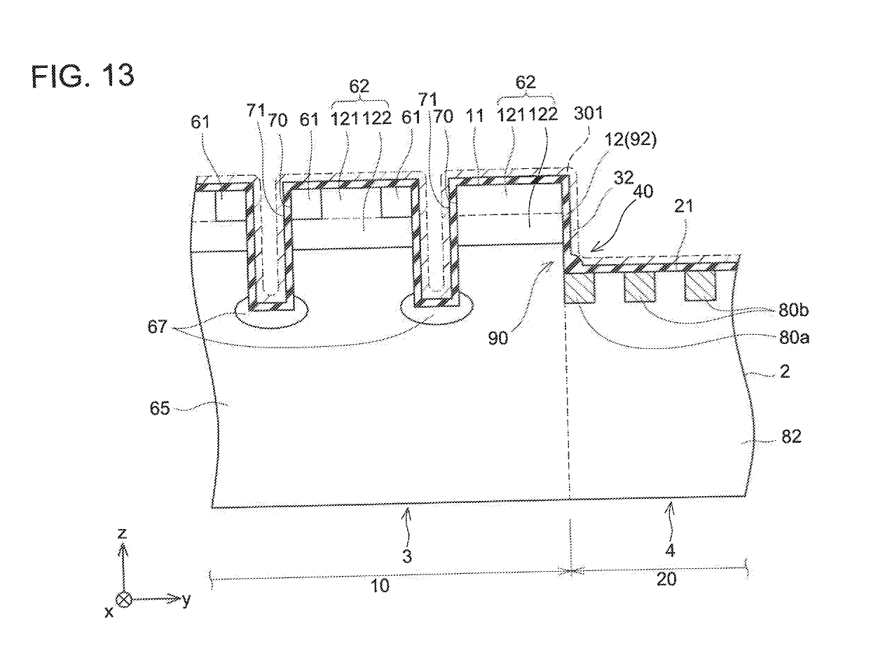

In a second embodiment, as shown in FIG. 12, the thickness of the separating insulation film 32 in an area A, which is close to the corner 40 is thicker than the thickness of the separating insulation film 32 in an area B, which is apart from the corner 40. In this case, the corner member 50 comprises a convexly curved surface 54 on a corner 40 side. The curved surface 54 covers the separating insulation film 32 at the corner 40. When this semiconductor device 1 is manufactured, as shown in FIG. 13, upon etching the separating insulation film material 301, the etching is performed such that the separating insulation film material 301 is left more in the area A close to the corner 40, than in the area B apart from the corner 40. For example, by adjusting an etching rate, a result that the separating insulation film material 301 is left more at the corner 40 can be obtained. According to a normal etching method, when the separating insulation film material 301 is etched, the separating insulation film material 301 naturally results in being left more in the area A close to the corner 40.

According to the semiconductor device 1 of the second embodiment, since the thickness of the separating insulation film 32 at the corner 40 is thick, the breakdown voltage of the separating insulation film 32 at the corner 40 can be enhanced.

### Third Embodiment

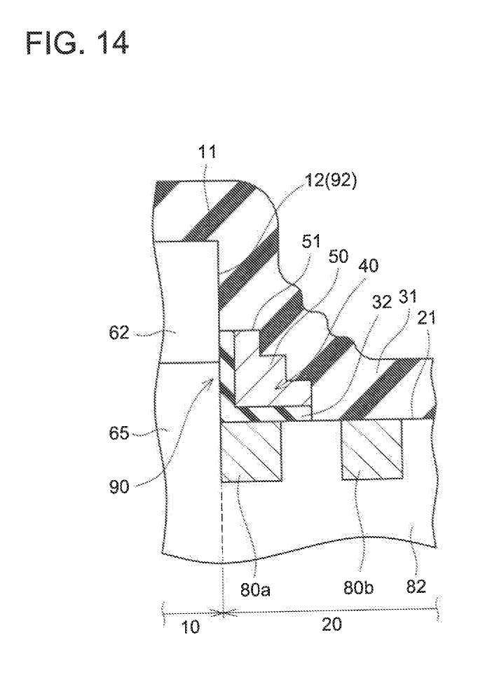

In a third embodiment, as shown in FIG. 14, the upper surface 51 of the corner member 50 is formed stepwise. The upper surface 51 of the corner member 50 is provided with a plurality of steps. Due to this, the upper surface 51 of the corner member 50 slopes downward stepwise from the side surface 92 of the step portion 90 toward the second portion 20.

### Fourth Embodiment

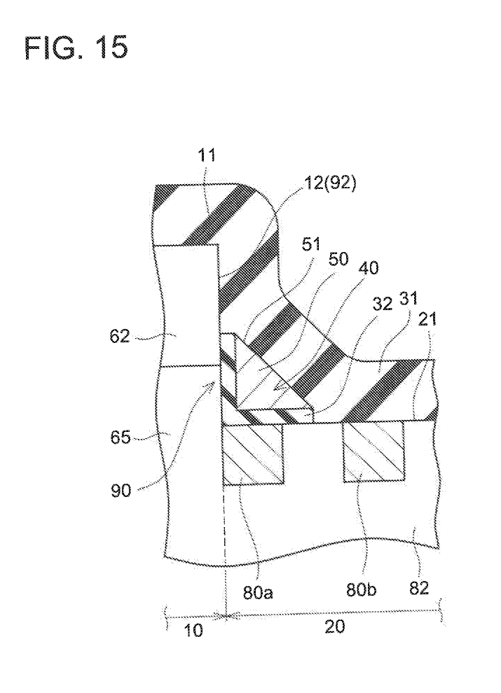

In a fourth embodiment, as shown in FIG. 15, the upper surface 51 of the corner member 50 is formed as a slant surface. Due to this, the upper surface 51 of the corner member 50 continuously slopes downward from the side surface 92 of the step portion 90 toward the second portion 20.

### Fifth Embodiment

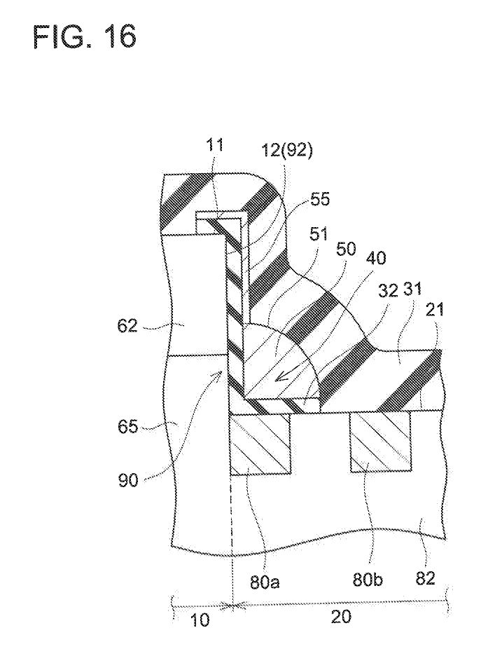

In a fifth embodiment, as shown in FIG. 16, the corner member 50 may comprise an extension portion 55. The extension portion 55 extends along the side surface 92 of the step portion 90 and the upper surface 11. With the extension portion 55 being provided, a part of the upper surface 51 of the corner member 50 is positioned upper than the upper surface 11 of the first portion 10. Therefore, the upper surface 51 of the corner member 50 comprises a part which slopes downward in a step-by-step manner and a part which continuously slopes downward from the side surface 92 of the step portion 90 toward the second portion 20. The extension portion 55 is covered with the covering insulation film 31. The extension portion 55 faces the base region 62 provided in the first portion 10 via the separating insulation film 32. The extension portion 55 may be connected to the front surface electrode 6 (not shown).

Further, in the above embodiments, the high breakdown voltage structure provided in the peripheral region 4 is an FLR structure provided with the plurality of FLRs 80, however, the high breakdown voltage structure is not limited thereto. In another embodiment, the high breakdown voltage structure may be a RESURF structure.

Further, in the above embodiments, the corner member 50 has electrical conductivity, however, the configuration is not limited thereto. In another embodiment, the corner member 50 may be made of an insulation material.

Further, in the above embodiments, the MOSFET is described as an example of the semiconductor element, however, the configuration is not limited thereto. In another embodiment, the semiconductor element may be an IGBT (Insulated Gate Bipolar Transistor).

Specific examples of the present invention have been described in detail, however, these are mere exemplary indications and thus do not limit the scope of the claims. The art described in the claims includes modifications and variations of the specific examples presented above.

Technical features described in the specification and the drawings may technically be useful alone or in various combinations, and are not limited to the combinations as originally claimed. Further, the art described in the description and the drawings may concurrently achieve a plurality of aims, and technical significance thereof resides in achieving any one of such aims,

Technical elements disclosed in the present specification will be described hereinbelow as examples. It should be noted that the respective technical elements are independent of one another, and are useful solely or in combinations.

In a semiconductor device, an upper surface of a corner member is preferably positioned lower than an upper surface of a first portion. Further, the upper surface of the corner member is preferably curved convexly upward.

A separating insulation film provided between a semiconductor substrate and the corner member may further be provided. The corner member may have electrical conductivity.

A thickness of the separating insulation film in an area close to a corner may be thicker than a thickness of the separating insulation film in an area apart from the corner.

The semiconductor substrate may comprise a first region of a first conductivity type exposed on a side surface of a step portion, a second region of the first conductivity type exposed on an upper surface of a second portion, and a third region of a second conductivity type provided between the first region and the second region. The corner member may face at least both of the first region and the second region via the separating insulation film.

A trench may be provided in the first portion. A gate electrode may be arranged in the trench. The corner member and the gate electrode are preferably made of the same material.

In a manufacturing method of the semiconductor device, forming of the corner member may comprise depositing a material of the corner member on the semiconductor substrate; and etching the corner member material deposited on the semiconductor substrate. The corner member may be formed by leaving the corner member material at the corner in the etching of the corner member material.

The method of manufacturing the semiconductor device may comprise forming the separating insulation film on an upper surface of the semiconductor substrate before the forming of the corner member. The corner member that has electrical conductivity may be formed on the separating insulation film in the forming of the corner member.

The forming of the separating insulation film may comprise depositing a material of the separating insulation film on the upper surface of the semiconductor substrate. Further, the forming of the separating insulation film may comprise etching the separating insulation film material so that a Thickness of the separating insulation film in an area close to the corner is thicker than a thickness of the separating insulation film in an area apart from the corner.

The tenth may be provided in the first portion. Further, the forming of the separating insulation film may comprise depositing the material of the separating insulation film on the upper surface of the semiconductor substrate, and etching the separating insulation film material deposited on the semiconductor substrate. Further, the forming of the corner member may comprise depositing the material of the corner member on an upper surface of the separating insulation film, and etching the corner member material deposited on the separating insulation film. A gate insulation film may be formed by disposing the separating insulation film material on an inner surface of the trench in the depositing of the separating insulation film material, and leaving the separating insulation film material on the inner surface of the trench in the etching of the separating insulation film material. Further, the gate electrode may be formed by depositing the corner member material inside the trench in the depositing of the corner member material and leaving the corner member material inside the trench in the etching of the corner member material.

### REFERENCE SIGNS LIST

1: Semiconductor device
2: Semiconductor substrate
3: Element region
4: Peripheral region
6: Front surface electrode
7: Rear surface electrode
10: First portion
20: Second portion
31: Covering insulation film
32: Separating insulation film
40: Corner
50: Corner member
51: Upper surface
54: Curved surface
55: Extension portion
61: Source region
62: Base region
63: Drain region
65: Drift region
67: Floating region
70: Trench
71: Gate insulation film
72: Gate electrode
73: Interlayer insulation film
80: Field limiting ring
82: Peripheral drift region
90: Step portion
121: Base contact region
122: Low-concentration base region.
301: Separating insulation film material
302: Corner member material
303: Covering insulation film material

1-12. (canceled)

13. A semiconductor device comprising:
a semiconductor substrate in which a semiconductor element is provided; and
a covering insulation film provided on the semiconductor substrate;
wherein
the semiconductor substrate comprises a first portion and a second portion which has a thickness thinner than a thickness of the first portion, and a step portion is provided at a part where the first portion and the second portion adjoin each other,
a corner member is provided at a corner between a side surface of the step portion and an upper surface of the second portion,
an upper surface of the corner member slopes downward from the side surface of the step portion toward the second portion, and
the covering insulation film extends over from the first portion to the second portion, and covers the corner member.

14. The semiconductor device according to claim 13, wherein
the upper surface of the corner member is positioned lower than an upper surface of the first portion.

15. The semiconductor device according to claim 13, wherein
the upper surface of the corner member is curved convexly upward.

16. The semiconductor device according to claim 13, further comprising a separating insulation film provided between the semiconductor substrate and the corner member,
wherein the corner member has electrical conductivity.

17. The semiconductor device according to claim 16, wherein
a thickness of the separating insulation film in an area close to the corner is thicker than the thickness of the separating insulation film in an area apart from the corner.

18. The semiconductor device according to claim 16, wherein
the semiconductor substrate comprises a first region of a first conductivity type exposed on the side surface of the step portion, a second region of the first conductivity type exposed on the upper surface of the second portion, and a third region of a second conductivity type provided between the first region and the second region, and
the corner member faces at least both of the first region and the second region via the separating insulation film.

19. The semiconductor device according to claim 13, wherein
a trench is provided in the first portion,
a gate electrode is arranged in the trench, and
the corner member and the gate electrode are made of a same material.

20. A method of manufacturing a semiconductor device that comprises:
a semiconductor substrate comprising a first portion, a second portion which has a thickness thinner than a thickness of the first portion, and a step portion provided at a part where the first portion and the second portion adjoin each other, and
a covering insulation film provided on the semiconductor substrate,
the method comprising:
forming a corner member at a corner between a side surface of the step portion and an upper surface of the second portion, wherein an upper surface of the corner member slopes downward from the side surface of the step portion toward the second portion; and
forming the covering insulation film extending over from the first portion to the second portion so that the corner member is covered by the covering insulation film.

21. The method of manufacturing the semiconductor device according to claim 20, wherein
the forming of the corner member comprises:
depositing a material of the corner member on the semiconductor substrate; and
etching the corner member material deposited on the semiconductor substrate, and
the corner member is formed by leaving the corner member material at the corner in the etching of the corner member material.

22. The method of manufacturing the semiconductor device according to claim 20, further comprising
forming a separating insulation film on an upper surface of the semiconductor substrate before the forming of the corner member,
wherein
the corner member that has electrical conductivity is formed on the separating insulation film in the forming of the corner member.

23. The method of manufacturing the semiconductor device according to claim 22, wherein
the forming of the separating insulation film comprises:
depositing a material of the separating insulation film on the upper surface of the semiconductor substrate, and
etching the separating insulation film material so that a thickness of the separating insulation film in an area close to the corner is thicker than the thickness of the separating insulation film in an area apart from the corner.

24. The method of manufacturing the semiconductor device according to claim 22, the semiconductor device being provided with a trench in the first portion, wherein
the forming of the separating insulation film comprises depositing a material of the separating insulation film on the upper surface of the semiconductor substrate, and etching the separating insulation film material deposited on the semiconductor substrate,
the forming of the corner member comprises depositing a material of the corner member on an upper surface of the separating insulation film, and etching the corner member material deposited on the separating insulation film,
the separating insulation film material is deposited on an inner surface of the trench in the depositing of the separating insulation film material,
a gate insulation film is formed by leaving the separating insulation film material on the inner surface of the trench in the etching of the separating insulation film material,
the corner member material is deposited inside the trench in the depositing of the corner member material, and
a gate electrode is formed by leaving the corner member material inside the trench in the etching of the corner member material.
